(19) United States
(12) Patent Application Publication
(10) Pub. No.: US 2022/0320418 A1
(43) Pub. Date: Oct. 6, 2022

(54) MAGNETIC MEMORY DEVICE

(71) Applicant: SAMSUNG ELECTRONICS CO., LTD., Suwon-si (KR)

(72) Inventors: Whankyun KIM, Seoul (KR); Joonmyoung LEE, Gwacheon-si (KR); Junho JEONG, Hwaseong-si (KR); Eunsun NOH, Yongin-si (KR); Jeong-Heon PARK, Hwaseong-si (KR); YoungJun CHO, Hwaseong-si (KR)

(21) Appl. No.: 17/502,411

(22) Filed: Oct. 15, 2021

(30) Foreign Application Priority Data
Apr. 2, 2021 (KR) 10-2021-0043278

(51) Int. Cl. H01L 43/02; H01L 43/10; H01L 43/12; H01L 27/22

(52) U.S. Cl. CPC H01L 43/02; H01L 43/10; H01L 43/12; H01L 27/228

(57) ABSTRACT

A magnetic memory device including a substrate; a first and second magnetic pattern stacked on the substrate; a tunnel barrier pattern between the first and second magnetic pattern; a bottom electrode between the substrate and the first magnetic pattern; a seed pattern between the bottom electrode and the first magnetic pattern; and a diffusion barrier pattern between the bottom electrode and the seed pattern, wherein a bottom surface of the at least one diffusion barrier pattern is in contact with a top surface of the bottom electrode, and a top surface of the at least one diffusion barrier pattern is in contact with a bottom surface of the seed pattern, the at least one diffusion barrier pattern includes a non-magnetic metal, or an alloy of the non-magnetic metal and a non-metal element, and the non-magnetic metal includes Ta, W, Nb, Ti, Cr, Zr, Hf, Mo, Al, Mg, or V.

### CROSS-REFERENCE TO RELATED APPLICATION

This U.S. non-provisional patent application claims priority under 35 U.S.C. § 119 to Korean Patent Application No. 10-2021-0043278, filed on Apr. 2, 2021, in the Korean Intellectual Property Office, the disclosure of which is hereby incorporated by reference in its entirety.

### BACKGROUND

### 1. Field

Embodiments relate to a magnetic memory device.

### 2. Description of the Related Art

As high-speed and/or low power consumption electronic devices have been demanded, high-speed and/or low-voltage semiconductor memory devices used therein have also been demanded. Magnetic memory devices have been developed as semiconductor memory devices capable of satisfying these demands. The magnetic memory devices may emerge as next-generation semiconductor memory devices because of their high-speed and/or non-volatile characteristics.

A magnetic memory device may include a magnetic tunnel junction (MTJ) pattern. The magnetic tunnel junction pattern may include two magnetic layers and an insulating layer between the two magnetic layers. A resistance value of the magnetic tunnel junction pattern may be changed depending on magnetization directions of the two magnetic layers. For example, when the magnetization directions of the two magnetic layers are anti-parallel to each other, the magnetic tunnel junction pattern may have a relatively high resistance value. When the magnetization directions of the two magnetic layers are parallel to each other, the magnetic tunnel junction pattern may have a relatively low resistance value. The magnetic memory device may write/read data using a difference between the resistance values of the magnetic tunnel junction pattern.

### SUMMARY

The embodiments may be realized by providing a magnetic memory device including a substrate; a first magnetic pattern and a second magnetic pattern sequentially stacked on the substrate; a tunnel barrier pattern between the first magnetic pattern and the second magnetic pattern; a bottom electrode between the substrate and the first magnetic pattern; a seed pattern between the bottom electrode and the first magnetic pattern; and at least one diffusion barrier pattern between the bottom electrode and the seed pattern, wherein a bottom surface of the at least one diffusion barrier pattern is in contact with a top surface of the bottom electrode, and a top surface of the at least one diffusion barrier pattern is in contact with a bottom surface of the seed pattern, the at least one diffusion barrier pattern includes a non-magnetic metal, or an alloy of the non-magnetic metal and a non-metal element, and the non-magnetic metal includes Ta, W, Nb, Ti, Cr, Zr, Hf, Mo, Al, Mg, or V.

The embodiments may be realized by providing a magnetic memory device including a substrate; a first magnetic pattern and a second magnetic pattern sequentially stacked on the substrate; a tunnel barrier pattern between the first magnetic pattern and the second magnetic pattern; a bottom electrode between the substrate and the first magnetic pattern; a seed pattern between the bottom electrode and the first magnetic pattern; and a first diffusion barrier pattern between the bottom electrode and the seed pattern, wherein the first diffusion barrier pattern includes a first non-magnetic metal, or an alloy of the first non-magnetic metal and a first non-metal element, and the first non-magnetic metal includes W, Nb, Ti, Cr, Zr, Hf, Mo, Al, Mg, or V.

The embodiments may be realized by providing a magnetic memory device including a substrate; a first magnetic pattern and a second magnetic pattern sequentially stacked on the substrate; a tunnel barrier pattern between the first magnetic pattern and the second magnetic pattern; a bottom electrode between the substrate and the first magnetic pattern; a seed pattern between the bottom electrode and the first magnetic pattern; and a first diffusion barrier pattern between the bottom electrode and the seed pattern, wherein the first diffusion barrier pattern is a crystalline layer of a first non-magnetic metal, and the first non-magnetic metal includes W, Nb, Ti, Cr, Zr, Hf, Mo, Al, Mg, or V.

### BRIEF DESCRIPTION OF THE DRAWINGS

Features will be apparent to those of skill in the art by describing in detail exemplary embodiments with reference to the attached drawings in which:

FIG. 1 is a circuit diagram of a unit memory cell of a magnetic memory device according to some embodiments.

FIG. 2 is a cross-sectional view of a magnetic memory device according to some embodiments.

FIG. 3 is a cross-sectional view of a magnetic memory device according to some embodiments.

FIG. 4 is a cross-sectional view of a magnetic memory device according to some embodiments.

FIG. 5 is a cross-sectional view of a magnetic memory device according to some embodiments.

FIG. 6 is a plan view of a magnetic memory device according to some embodiments.

FIG. 7 is a cross-sectional view taken along a line I-I′ of FIG. 6.

FIGS. 8 to 10 are cross-sectional views corresponding to the line I-I′ of FIG. 6 of stages in a method of manufacturing a magnetic memory device, according to some embodiments.

### DETAILED DESCRIPTION

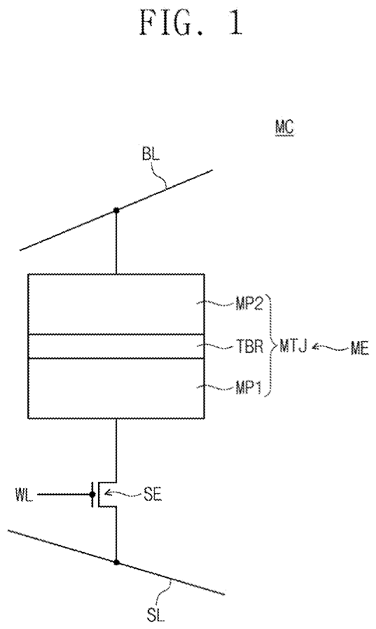

FIG. 1 is a circuit diagram of a unit memory cell of a magnetic memory device according to some embodiments.

Referring to FIG. 1, a unit memory cell MC may include a memory element ME and a selection element SE. The memory element ME and the selection element SE may be electrically connected in series to each other. The memory element ME may be connected between a bit line BL and the selection element SE. The selection element SE may be connected between the memory element ME and a source line SL and may be controlled by a word line WL. In an implementation, the selection element SE may include a bipolar transistor or a MOS field effect transistor.

The memory element ME may include a magnetic tunnel junction MTJ. The magnetic tunnel junction MTJ may include a first magnetic pattern MP1, a second magnetic pattern MP2, and a tunnel barrier pattern TBR between the first and second magnetic patterns MP1 and MP2. One of the first and second magnetic patterns MP1 and MP2 may be a reference magnetic pattern of which a magnetization direction is fixed in one direction regardless of an external magnetic field under a general use environment. The other of the first and second magnetic patterns MP1 and MP2 may be a free magnetic pattern of which a magnetization direction is changeable between two stable magnetization directions by an external magnetic field. An electrical resistance of the magnetic tunnel junction MTJ when the magnetization directions of the reference and free magnetic patterns are anti-parallel to each other may be much greater than that of the magnetic tunnel junction MTJ when the magnetization directions of the reference and free magnetic patterns are parallel to each other. In other words, the electrical resistance of the magnetic tunnel junction MTJ may be adjusted by changing the magnetization direction of the free magnetic pattern. Thus, logical data may be stored in the memory element ME of the unit memory cell MC by using an electrical resistance difference according to the magnetization directions of the reference and free magnetic patterns.

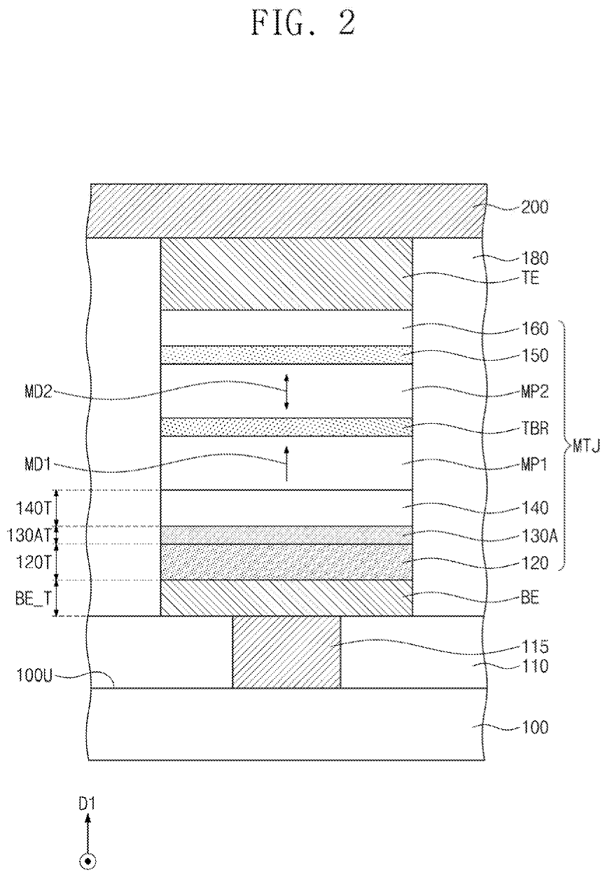

FIG. 2 is a cross-sectional view of a magnetic memory device according to some embodiments.

Referring to FIG. 2, a first interlayer insulating layer 110 may be on a substrate 100, and a lower contact plug 115 may be in the first interlayer insulating layer 110. The substrate 100 may be a semiconductor substrate that includes, e.g., silicon, silicon on an insulator (SOI), silicon-germanium (SiGe), germanium (Ge), or gallium-arsenic (GaAs). In an implementation, the first interlayer insulating layer 110 may include, e.g., an oxide layer, a nitride layer, or an oxynitride layer. As used herein, the term “or” is not an exclusive term, e.g., “A or B” would include A, B, or A and B.

The lower contact plug 115 may penetrate the first interlayer insulating layer 110 and may be electrically connected to the substrate 100. A selection element (see SE of FIG. 1) may be in the substrate 100, and the selection element may be, e.g., a field effect transistor. The lower contact plug 115 may be electrically connected to one terminal of the selection element. The lower contact plug 115 may include a doped semiconductor material (e.g., doped silicon), a metal (e.g., tungsten, titanium, or tantalum), a metal-semiconductor compound (e.g., a metal silicide), or a conductive metal nitride (e.g., titanium nitride, tantalum nitride, or tungsten nitride).

A bottom electrode BE, a magnetic tunnel junction pattern MTJ, and a top electrode TE may be sequentially stacked on the lower contact plug 115. The bottom electrode BE may be between the lower contact plug 115 and the magnetic tunnel junction pattern MTJ, and the magnetic tunnel junction pattern MTJ may be between the bottom electrode BE and the top electrode TE. The bottom electrode BE may be electrically connected to the lower contact plug 115. In an implementation, the bottom electrode BE may include a conductive metal nitride (e.g., titanium nitride or tantalum nitride). In an implementation, the top electrode TE may include, e.g., a metal (e.g., Ta, W, Ru, or Ir) or a conductive metal nitride (e.g., TiN).

The magnetic tunnel junction pattern MTJ may include a first magnetic pattern MP1, a second magnetic pattern MP2, a tunnel barrier pattern TBR between the first magnetic pattern MP1 and the second magnetic pattern MP2, a seed pattern 140 between the bottom electrode BE and the first magnetic pattern MP1, a first diffusion barrier pattern 130A between the bottom electrode BE and the seed pattern 140, and a blocking pattern 120 between the bottom electrode BE and the first diffusion barrier pattern 130A.

The blocking pattern 120 may include an amorphous metal layer. In an implementation, the blocking pattern 120 may include an amorphous metal layer made of a ferromagnetic element, a non-metal element, and a non-magnetic metal element. The ferromagnetic element may include cobalt, iron, or nickel, and the non-metal element may include boron, nitrogen, or oxygen. The non-magnetic metal element may include tantalum (Ta), tungsten (W), niobium (Nb), titanium (Ti), chromium (Cr), zirconium (Zr), hafnium (Hf), molybdenum (Mo), aluminum (Al), magnesium (Mg), ruthenium (Ru), or vanadium (V). In an implementation, the blocking pattern 120 may include, e.g., CoFeBTa. In an implementation, the blocking pattern 120 may include an amorphous metal layer made of the non-magnetic metal element and the non-metal element. In an implementation, the blocking pattern 120 may include, e.g., ruthenium oxide or TaB.

The blocking pattern 120 may help prevent a crystal structure of the bottom electrode BE from being transferred to the seed pattern 140. In an implementation, it is possible to help prevent the crystal structure of the bottom electrode BE from affecting crystal structure and orientation of the first magnetic pattern MP1 through the seed pattern 140.

The first diffusion barrier pattern 130A may include, e.g., a first non-magnetic metal, or an alloy of the first non-magnetic metal and a first non-metal element. In an implementation, the first non-magnetic metal may include, e.g., W, Nb, Ti, Cr, Zr, Hf, Mo, Al, Mg, or V, and the first non-metal element may include, e.g., Si, N, or B. In an implementation, the first diffusion barrier pattern 130A may be made of (e.g., may consist of) the first non-magnetic metal, or the alloy of the first non-magnetic metal and the first non-metal element. In an implementation, the first diffusion barrier pattern 130A may be a crystalline layer of the first non-magnetic metal. In an implementation, the first diffusion barrier pattern 130A may be a crystalline or amorphous layer of the alloy of the first non-magnetic metal and the first non-metal element. The first diffusion barrier pattern 130A may be a single metal layer made of the first non-magnetic metal, e.g., a Mo single metal layer.

The first diffusion barrier pattern 130A may help prevent metal atoms in the bottom electrode BE and the blocking pattern 120 from being diffused into the seed pattern 140 and upper patterns (e.g., the first magnetic pattern MP1) on the seed pattern 140. The first diffusion barrier pattern 130A may be referred to as a diffusion barrier pattern.

The seed pattern 140 may include a material that facilitates crystal growth of the first magnetic pattern MP1. In an implementation, the seed pattern 140 may include, e.g., chromium (Cr), iridium (Ir), or ruthenium (Ru).

The bottom electrode BE, the blocking pattern 120, the first diffusion barrier pattern 130A, and the seed pattern 140 may have thicknesses in a first direction D1 perpendicular to a top surface 100U of the substrate 100. A thickness 130AT of the first diffusion barrier pattern 130A may be less than a thickness 120T of the blocking pattern 120 and may be less than a thickness 140T of the seed pattern 140. The thickness 130AT of the first diffusion barrier pattern 130A may be less than a thickness BE_T of the bottom electrode BE. When the first diffusion barrier pattern 130A is a crystalline layer (e.g., the crystalline layer of the first non-magnetic metal), the thickness 130AT of the first diffusion barrier pattern 130A may range from, e.g., 5 Å to 15 Å. Maintaining the thickness 130AT of the first diffusion barrier pattern 130A at 5 Å or greater may help ensure that diffusion of metal atoms in lower patterns (e.g., the bottom electrode BE and the blocking pattern 120) under the first diffusion barrier pattern 130A may be prevented. Maintaining the thickness 130AT of the first diffusion barrier pattern 130A at 15X or less may help ensure that a crystal structure of the first diffusion barrier pattern 130A does not affect crystal growth and orientation of the seed pattern 140 and the upper patterns (e.g., the first magnetic pattern MP1) on the seed pattern 140, and thus preventing deterioration of characteristics of the magnetic tunnel junction pattern MTJ.

In an implementation, the first magnetic pattern MP1 may include a reference layer having a magnetization direction MD1 fixed in one direction, and the second magnetic pattern MP2 may include a free layer having a changeable magnetization direction MD2. The magnetization direction MD2 of the second magnetic pattern MP2 may be changeable to be parallel or anti-parallel to the magnetization direction MD1 of the first magnetic pattern MP1. In an implementation, as illustrated in FIG. 2, the first magnetic pattern MP1 may include the reference layer and the second magnetic pattern MP2 may include the free layer. In an implementation, the first magnetic pattern MP1 may include the free layer and the second magnetic pattern MP2 may include the reference layer.

The magnetization directions MD1 and MD2 of the first and second magnetic patterns MP1 and MP2 may be substantially perpendicular to an interface of the first magnetic pattern MP1 and the tunnel barrier pattern TBR and may be substantially perpendicular to the top surface 100U of the substrate 100. In an implementation, each of the first and second magnetic patterns MP1 and MP2 may include an intrinsic perpendicular magnetic material or an extrinsic perpendicular magnetic material. The intrinsic perpendicular magnetic material may include a material which has a perpendicular magnetization property even though an external factor does not exist. The intrinsic perpendicular magnetic material may include, e.g., a perpendicular magnetic material (e.g., CoFeTb, CoFeGd, or CoFeDy), a perpendicular magnetic material having a L1₀ structure, a CoPt alloy having a hexagonal close packed (HCP) lattice structure, or a perpendicular magnetic structure. The perpendicular magnetic material having the L1₀ structure may include, e.g., FePt having the L1₀ structure, FePd having the L1₀ structure, CoPd having the L1₀ structure, or CoPt having the L1₀ structure. The perpendicular magnetic structure may include magnetic layers and non-magnetic layers, which are alternately and repeatedly stacked. In an implementation, the perpendicular magnetic structure may include, e.g., (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where ‘n’ denotes the number of bilayers. The extrinsic perpendicular magnetic material may include a material which has an intrinsic horizontal magnetization property but has a perpendicular magnetization property by an external factor. In an implementation, the extrinsic perpendicular magnetic material may have the perpendicular magnetization property by magnetic anisotropy induced by a junction of the tunnel barrier pattern TBR and the first magnetic pattern MP1 (or the second magnetic pattern MP2). The extrinsic perpendicular magnetic material may include, e.g., CoFeB.

In an implementation, each of the first and second magnetic patterns MP1 and MP2 may include a Co-based Heusler alloy. The tunnel barrier pattern TBR may include, e.g., a magnesium oxide (MgO) layer, a titanium oxide (TiO) layer, an aluminum oxide (AlO) layer, a magnesium-zinc oxide (MgZnO) layer, or a magnesium-boron oxide (MgBO) layer.

The magnetic tunnel junction pattern MTJ may further include a capping pattern 160 between the second magnetic pattern MP2 and the top electrode TE, and a non-magnetic pattern 150 between the second magnetic pattern MP2 and the capping pattern 160. The non-magnetic pattern 150 may include, e.g., a magnesium oxide (MgO) layer, a titanium oxide (TiO) layer, an aluminum oxide (AlO) layer, a magnesium-zinc oxide (MgZnO) layer, or a magnesium-boron oxide (MgBO) layer. In an implementation, the non-magnetic pattern 150 may include the same material as the tunnel barrier pattern TBR. Magnetic anisotropy of the second magnetic pattern MP2 may be improved by magnetic anisotropy induced at an interface between the non-magnetic pattern 150 and the second magnetic pattern MP2. The capping pattern 160 may help prevent deterioration of the second magnetic pattern MP2. In an implementation, the capping pattern 160 may include, e.g., tantalum (Ta), aluminum (Al), copper (Cu), gold (Au), silver (Ag), titanium (Ti), tantalum nitride (TaN), or titanium nitride (TiN).

When a high-temperature subsequent process of 400 degrees Celsius or more is performed on the magnetic tunnel junction pattern MTJ, metal atoms in the bottom electrode BE and the blocking pattern 120 could be diffused into the seed pattern 140 and the upper patterns (e.g., the first magnetic pattern MP1) on the seed pattern 140. In this case, crystallinity of the seed pattern 140 and the first magnetic pattern MP1 could be deteriorated, and a tunnel magnetoresistance (TMR) characteristic of the magnetic tunnel junction pattern MTJ including the first magnetic pattern MP1 could also be deteriorated.

According to the embodiments, the first diffusion barrier pattern 130A may be under the seed pattern 140 (e.g., between the seed pattern 140 and the blocking pattern 120) and may help prevent metal atoms in lower patterns (e.g., the bottom electrode BE and the blocking pattern 120) under the first diffusion barrier pattern 130A from being diffused into the seed pattern 140 and the upper patterns (e.g., the first magnetic pattern MP1) on the seed pattern 140. Thus, deterioration of crystallinity of the seed pattern 140 and the first magnetic pattern MP1 may be prevented. As a result, the tunnel magnetoresistance (TMR) characteristic of the magnetic tunnel junction pattern MTJ may be improved, and high-temperature reliability of the magnetic tunnel junction pattern MTJ may be improved.

A second interlayer insulating layer 180 may be on the first interlayer insulating layer 110 and may cover sidewalls of the bottom electrode BE, the magnetic tunnel junction pattern MTJ and the top electrode TE. In an implementation, the second interlayer insulating layer 180 may include, e.g., an oxide layer, a nitride layer, or an oxynitride layer.

An upper interconnection line 200 may be on the second interlayer insulating layer 180 and may be (e.g., electrically) connected to the top electrode TE. The upper interconnection line 200 may be connected to the magnetic tunnel junction pattern MTJ through the top electrode TE and may function as the bit line BL of FIG. 1. The upper interconnection line 200 may include a metal (e.g., copper) or a conductive metal nitride.

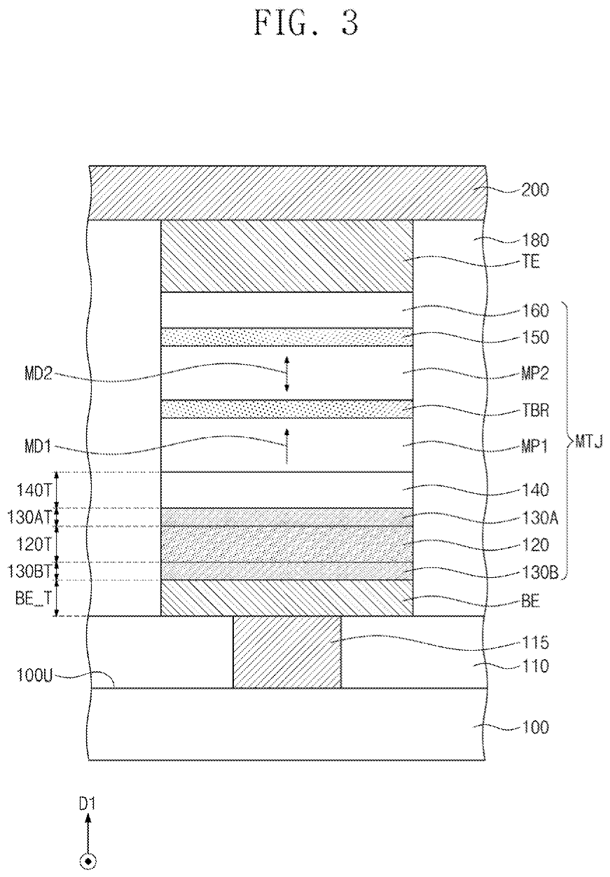

FIG. 3 is a cross-sectional view of a magnetic memory device according to some embodiments. Hereinafter, differences between the present embodiments and the embodiments described with reference to FIG. 2 may be mainly described for the purpose of ease and convenience in explanation.

Referring to FIG. 3, the magnetic tunnel junction pattern MTJ may further include a second diffusion barrier pattern 130B between the bottom electrode BE and the blocking pattern 120. The first diffusion barrier pattern 130A may be between the seed pattern 140 and the blocking pattern 120, and the second diffusion barrier pattern 130B may be between the bottom electrode BE and the blocking pattern 120. The first and second diffusion barrier patterns 130A and 130B may together be referred to as a diffusion barrier pattern.

The first diffusion barrier pattern 130A may include the first non-magnetic metal, or the alloy of the first non-magnetic metal and the first non-metal element. In an implementation, the first non-magnetic metal may include, e.g., Ta, W, Nb, Ti, Cr, Zr, Hf, Mo, Al, Mg, or V, and the first non-metal element may include, e.g., Si, N, or B. The first diffusion barrier pattern 130A may be made of the first non-magnetic metal, or the alloy of the first non-magnetic metal and the first non-metal element. In an implementation, the first diffusion barrier pattern 130A may be a crystalline layer of the first non-magnetic metal. In an implementation, the first diffusion barrier pattern 130A may be a crystalline or amorphous layer of the alloy of the first non-magnetic metal and the first non-metal element. The first diffusion barrier pattern 130A may be a single metal layer made of the first non-magnetic metal, e.g., a Mo single metal layer.

The second diffusion barrier pattern 130B may include a second non-magnetic metal, or an alloy of the second non-magnetic metal and a second non-metal element. In an implementation, the second non-magnetic metal may include, e.g., Ta, W, Nb, Ti, Cr, Zr, Hf, Mo, Al, Mg, or V, and the second non-metal element may include, e.g., Si, N, or B. The second diffusion barrier pattern 130B may be made of (e.g., may consist of) the second non-magnetic metal, or the alloy of the second non-magnetic metal and the second non-metal element. In an implementation, the second diffusion barrier pattern 130B may be a crystalline layer of the second non-magnetic metal. In an implementation, the second diffusion barrier pattern 130B may be a crystalline or amorphous layer of the alloy of the second non-magnetic metal and the second non-metal element. The second diffusion barrier pattern 130B may be a single metal layer made of the second non-magnetic metal, e.g., a Mo single metal layer.

The second diffusion barrier pattern 130B may help prevent metal atoms in the bottom electrode BE from being diffused into the blocking pattern 120 and upper patterns (e.g., the seed pattern 140 and the first magnetic pattern MP1) on the blocking pattern 120.

Each of the bottom electrode BE, the blocking pattern 120, the first and second diffusion barrier patterns 130A and 130B, and the seed pattern 140 may have a thickness in the first direction D1. A thickness 130AT of the first diffusion barrier pattern 130A may be less than a thickness 120T of the blocking pattern 120 and may be less than a thickness 140T of the seed pattern 140. The thickness 130AT of the first diffusion barrier pattern 130A may be less than a thickness BE_T of the bottom electrode BE. A thickness 130BT of the second diffusion barrier pattern 130B may be less than the thickness 120T of the blocking pattern 120 and may be less than the thickness BE_T of the bottom electrode BE. The thickness 130BT of the second diffusion barrier pattern 130B may be less than the thickness 140T of the seed pattern 140.

When the second diffusion barrier pattern 130B is a crystalline layer (e.g., the crystalline layer of the second non-magnetic metal), the thickness 130BT of the second diffusion barrier pattern 130B may range from, e.g., 5 Å to 15 Å. Maintaining the thickness 130BT of the second diffusion barrier pattern 130B at 5 Å or greater may help ensure that diffusion of metal atoms in lower patterns (e.g., the bottom electrode BE) under the second diffusion barrier pattern 130B may be prevented. Maintaining the thickness 130BT of the second diffusion barrier pattern 130B at 15 Å or less may help ensure that a crystal structure of the second diffusion barrier pattern 130B does not affect crystal growth and orientation of upper patterns (e.g., the blocking pattern 120, the seed pattern 140 and the first magnetic pattern MP1) on the second diffusion barrier pattern 130B, and thus deterioration of characteristics of the magnetic tunnel junction pattern MTJ may be prevented.

According to the present embodiments, the second diffusion barrier pattern 130B may be between the bottom electrode BE and the blocking pattern 120 and may help prevent metal atoms in the lower patterns (e.g., the bottom electrode BE) under the second diffusion barrier pattern 130B from being diffused into the blocking pattern 120. As a result, the amorphous state of the blocking pattern 120 may be easily maintained, and a crystal structure of the bottom electrode BE may be easily blocked by the blocking pattern 120.

In addition, the first diffusion barrier pattern 130A may be between the blocking pattern 120 and the seed pattern 140, and it is possible to help prevent metal atoms in lower patterns (e.g., the bottom electrode BE and the blocking pattern 120) under the first diffusion barrier pattern 130A from being diffused into the seed pattern 140 and the upper patterns (e.g., the first magnetic pattern MP1) on the seed pattern 140.

According to the present embodiments, deterioration of crystallinity of the seed pattern 140 and the first magnetic pattern MP1 may be prevented. As a result, the tunnel magnetoresistance (TMR) characteristic of the magnetic tunnel junction pattern MTJ may be improved, and the high-temperature reliability of the magnetic tunnel junction pattern MTJ may be improved.

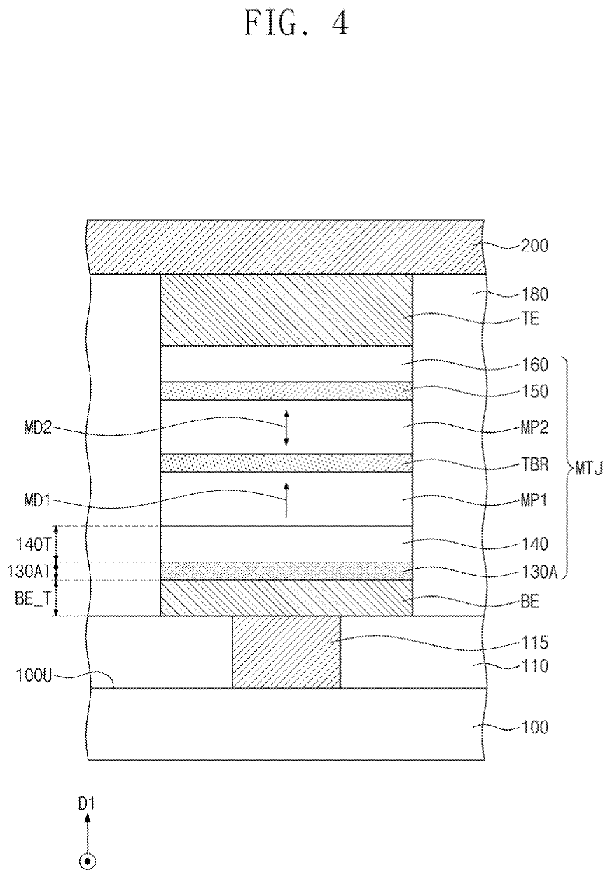

FIG. 4 is a cross-sectional view of a magnetic memory device according to some embodiments. Hereinafter, differences between the present embodiments and the embodiments described with reference to FIG. 2 may be mainly described for the purpose of ease and convenience in explanation.

Referring to FIG. 4, the magnetic tunnel junction pattern MTJ may include the first magnetic pattern MP1, the second magnetic pattern MP2, the tunnel barrier pattern TBR between the first magnetic pattern MP1 and the second magnetic pattern MP2, the seed pattern 140 between the bottom electrode BE and the first magnetic pattern MP1, and the first diffusion barrier pattern 130A between the bottom electrode BE and the seed pattern 140. In the present embodiments, the magnetic tunnel junction pattern MTJ may not include the blocking pattern 120 of FIG. 2. A bottom (e.g., substrate 100-facing) surface of the first diffusion barrier pattern 130A may be in contact (e.g., direct contact) with a top surface (e.g., surface facing away from the substrate 100 in the first direction D1) of the bottom electrode BE, and a top surface of the first diffusion barrier pattern 130A may be in contact (e.g., direct contact) with a bottom surface of the seed pattern 140. The first diffusion barrier pattern 130A may be referred to as a diffusion barrier pattern.

The first diffusion barrier pattern 130A may include the first non-magnetic metal, or the alloy of the first non-magnetic metal and the first non-metal element. In an implementation, the first non-magnetic metal may include, e.g., Ta, W, Nb, Ti, Cr, Zr, Hf, Mo, Al, Mg, or V, and the first non-metal element may include, e.g., Si, N, or B. In an implementation, the first diffusion barrier pattern 130A may be made of the first non-magnetic metal, or the alloy of the first non-magnetic metal and the first non-metal element. In an implementation, the first diffusion barrier pattern 130A may be a crystalline layer of the first non-magnetic metal. In an implementation, the first diffusion barrier pattern 130A may be a crystalline or amorphous layer of the alloy of the first non-magnetic metal and the first non-metal element. The first diffusion barrier pattern 130A may be a single metal layer made of the first non-magnetic metal, e.g., a Mo single metal layer.

The first diffusion barrier pattern 130A may help prevent metal atoms in the bottom electrode BE from being diffused into the seed pattern 140 and upper patterns (e.g., the first magnetic pattern MP1) on the seed pattern 140. In an implementation, the first diffusion barrier pattern 130A may help prevent the crystal structure of the bottom electrode BE from being transferred to the seed pattern 140. In an implementation, it is possible to prevent the crystal structure of the bottom electrode BE from affecting crystal structure and orientation of the first magnetic pattern MIP through the seed pattern 140.

Each of the bottom electrode BE, the first diffusion barrier pattern 130A, and the seed pattern 140 may have a thickness in the first direction D1. A thickness 130AT of the first diffusion barrier pattern 130A may be less than a thickness BE_T of the bottom electrode BE and may be less than a thickness 140T of the seed pattern 140.

According to the present embodiments, deterioration of crystallinity of the seed pattern 140 and the first magnetic pattern MP1 may be prevented. As a result, the tunnel magnetoresistance (TMR) characteristic of the magnetic tunnel junction pattern MTJ may be improved, and the high-temperature reliability of the magnetic tunnel junction pattern MTJ may be improved. In addition, the magnetic tunnel junction pattern MTJ may not include the blocking pattern 120, and a structure of the magnetic tunnel junction pattern MTJ may be simplified.

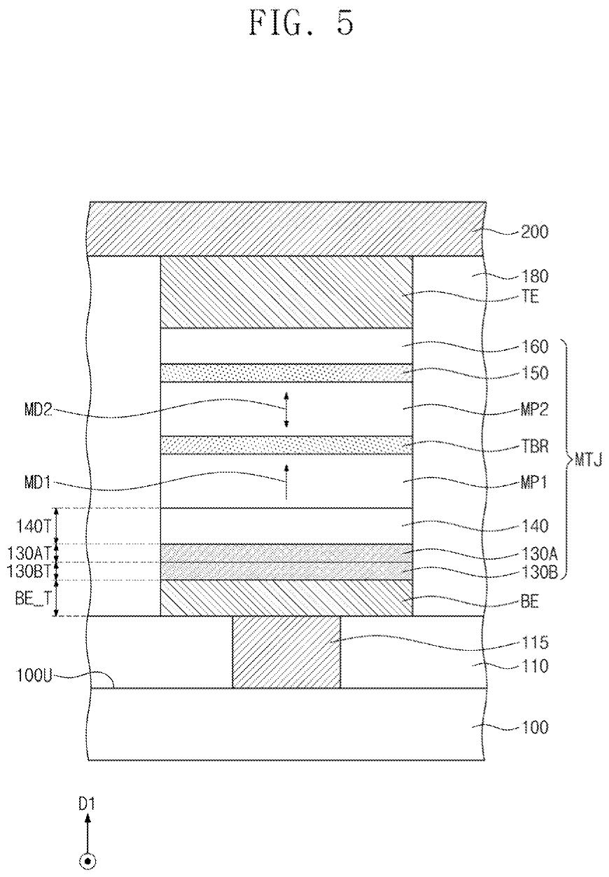

FIG. 5 is a cross-sectional view of a magnetic memory device according to some embodiments. Hereinafter, differences between the present embodiments and the embodiments described with reference to FIG. 2 may be mainly described for the purpose of ease and convenience in explanation.

Referring to FIG. 5, the magnetic tunnel junction pattern MTJ may include the first magnetic pattern MP1, the second magnetic pattern MP2, the tunnel barrier pattern TBR between the first magnetic pattern MP1 and the second magnetic pattern MP2, the seed pattern 140 between the bottom electrode BE and the first magnetic pattern MP1, the first diffusion barrier pattern 130A between the bottom electrode BE and the seed pattern 140, and a second diffusion barrier pattern 130B between the bottom electrode BE and the first diffusion barrier pattern 130A. In the present embodiments, the magnetic tunnel junction pattern MTJ may not include the blocking pattern 120 of FIG. 2. The first and second diffusion barrier patterns 130A and 130B may be between the bottom electrode BE and the seed pattern 140 and may be stacked. A top surface of the first diffusion barrier pattern 130A may be in contact (e.g., direct contact) with a bottom surface of the seed pattern 140, and a bottom surface of the second diffusion barrier pattern 130B may be in contact (e.g., direct contact) with a top surface of the bottom electrode BE. The first and second diffusion barrier patterns 130A and 130B may together be referred to as a diffusion barrier pattern.

The first diffusion barrier pattern 130A may include the first non-magnetic metal, or the alloy of the first non-magnetic metal and the first non-metal element. In an implementation, the first non-magnetic metal may include, e.g., Ta, W, Nb, Ti, Cr, Zr, Hf, Mo, Al, Mg, or V, and the first non-metal element may include, e.g., Si, N, or B. In an implementation, the first diffusion barrier pattern 130A may be made of the first non-magnetic metal, or the alloy of the first non-magnetic metal and the first non-metal element. In an implementation, the first diffusion barrier pattern 130A may be a crystalline layer of the first non-magnetic metal. In an implementation, the first diffusion barrier pattern 130A may be a crystalline or amorphous layer of the alloy of the first non-magnetic metal and the first non-metal element. In an implementation, the first diffusion barrier pattern 130A may be a single metal layer made of the first non-magnetic metal.

The second diffusion barrier pattern 130B may include a second non-magnetic metal, or an alloy of the second non-magnetic metal and a second non-metal element. In an implementation, the second non-magnetic metal may include, e.g., Ta, W, Nb, Ti, Cr, Zr, Hf, Mo, Al, Mg, or V, and the second non-metal element may include, e.g., Si, N, or B. In an implementation, the second diffusion barrier pattern 130B may be made of the second non-magnetic metal, or the alloy of the second non-magnetic metal and the second non-metal element. In an implementation, the second diffusion barrier pattern 130B may be a crystalline layer of the second non-magnetic metal. In an implementation, the second diffusion barrier pattern 130B may be a crystalline or amorphous layer of the alloy of the second non-magnetic metal and the second non-metal element. In an implementation, the second diffusion barrier pattern 130B may be a single metal layer made of the second non-magnetic metal. In an implementation, the second diffusion barrier pattern 130B may include a different material from that of the first diffusion barrier pattern 130A.

The first and second diffusion barrier patterns 130A and 130B may help prevent metal atoms in the bottom electrode BE from being diffused into the seed pattern 140 and upper patterns (e.g., the first magnetic pattern MP1) on the seed pattern 140. In an implementation, the first and second diffusion barrier patterns 130A and 130B may help prevent the crystal structure of the bottom electrode BE from being transferred to the seed pattern 140. In an implementation, it is possible to help prevent the crystal structure of the bottom electrode BE from affecting crystal structure and orientation of the first magnetic pattern MP1 through the seed pattern 140.

Each of the bottom electrode BE, the first and second diffusion barrier patterns 130A and 130B, and the seed pattern 140 may have a thickness in the first direction D1. A thickness 130AT of the first diffusion barrier pattern 130A may be less than a thickness BE_T of the bottom electrode BE and may be less than a thickness 140T of the seed pattern 140. A thickness 130BT of the second diffusion barrier pattern 130B may be less than the thickness BE_T of the bottom electrode BE and may be less than the thickness 140T of the seed pattern 140. The thickness 130BT of the second diffusion barrier pattern 130B may be equal to or different from the thickness 130AT of the first diffusion barrier pattern 130A.

According to the present embodiments, deterioration of crystallinity of the seed pattern 140 and the first magnetic pattern MP1 may be prevented. As a result, the tunnel magnetoresistance (TMR) characteristic of the magnetic tunnel junction pattern MTJ may be improved, and the high-temperature reliability of the magnetic tunnel junction pattern MTJ may be improved. In an implementation, the magnetic tunnel junction pattern MTJ may not include the blocking pattern 120, and a structure of the magnetic tunnel junction pattern MTJ may be simplified.

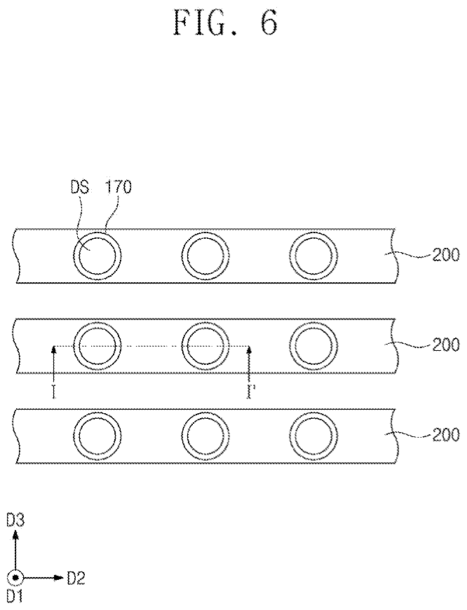

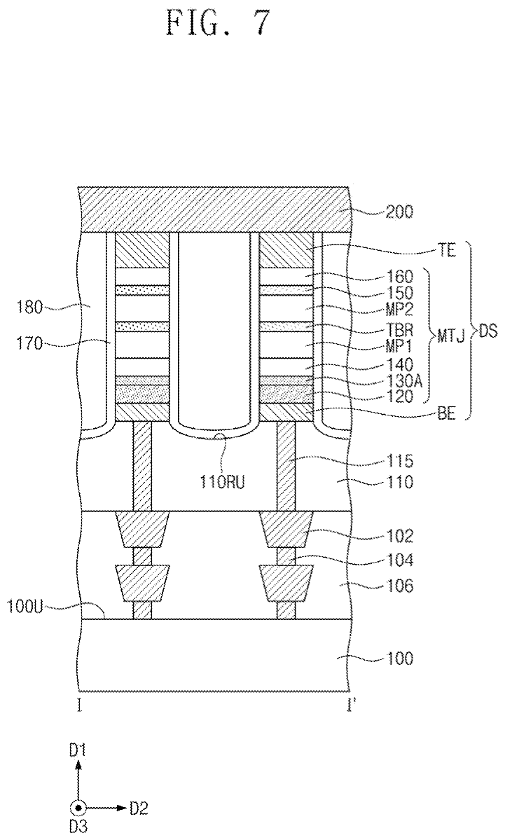

FIG. 6 is a plan view of a magnetic memory device according to some embodiments, and FIG. 7 is a cross-sectional view taken along a line I-I′ of FIG. 6. Hereinafter, the descriptions to the same features as described with reference to FIGS. 2 to 5 may be omitted or mentioned briefly for the purpose of ease and convenience in explanation.

Referring to FIGS. 6 and 7, lower interconnection lines 102 and lower contacts 104 may be on a substrate 100. The lower interconnection lines 102 may be spaced apart from a top surface 100U of the substrate 100 in the first direction D1 perpendicular to the top surface 100U of the substrate 100. The lower contacts 104 may be between the substrate 100 and the lower interconnection lines 102, and each of the lower interconnection lines 102 may be electrically connected to the substrate 100 through a corresponding one of the lower contacts 104. The lower interconnection lines 102 and the lower contacts 104 may include a metal (e.g., copper).

Selection elements (see SE of FIG. 1) may be in the substrate 100. The selection elements may be, e.g., field effect transistors. Each of the lower interconnection lines 102 may be electrically connected to one terminal of a corresponding one of the selection elements through the corresponding lower contact 104.

A lower interlayer insulating layer 106 may be on the substrate 100 and may cover the lower interconnection lines 102 and the lower contacts 104. Top surfaces of uppermost ones of the lower interconnection lines 102 may be substantially coplanar with a top surface of the lower interlayer insulating layer 106. The top surfaces of the uppermost lower interconnection lines 102 may be at substantially the same height as the top surface of the lower interlayer insulating layer 106. In the present specification, the term ‘height’ may mean a distance measured from the top surface 100U of the substrate 100 in the first direction D1. In an implementation, the lower interlayer insulating layer 106 may include, e.g., an oxide, a nitride, or an oxynitride.

A first interlayer insulating layer 110 may be on the lower interlayer insulating layer 106 and may cover the top surfaces of the uppermost lower interconnection lines 102.

A plurality of lower contact plugs 115 may be in the first interlayer insulating layer 110. The plurality of lower contact plugs 115 may be spaced apart from each other in a second direction D2 and a third direction D3 which are parallel to the top surface 100U of the substrate 100. The second direction D2 and the third direction D3 may intersect each other. Each of the plurality of lower contact plugs 115 may penetrate the first interlayer insulating layer 110 and may be connected to a corresponding one of the lower interconnection lines 102. The plurality of lower contact plugs 115 may include a doped semiconductor material (e.g., doped silicon), a metal (e.g., tungsten, titanium, or tantalum), a metal-semiconductor compound (e.g., a metal silicide), or a conductive metal nitride (e.g., titanium nitride, tantalum nitride, or tungsten nitride).

A plurality of data storage patterns DS may be on the first interlayer insulating layer 110 and may be spaced apart from each other in the second direction D2 and the third direction D3. The plurality of data storage patterns DS may be on the plurality of lower contact plugs 115, respectively, and may be connected to the plurality of lower contact plugs 115, respectively.

Each of the plurality of data storage patterns DS may include a bottom electrode BE, a magnetic tunnel junction pattern MTJ and a top electrode TE, which are sequentially stacked on a corresponding lower contact plug 115. The bottom electrode BE may be between the corresponding lower contact plug 115 and the magnetic tunnel junction pattern MTJ, and the magnetic tunnel junction pattern MTJ may be between the bottom electrode BE and the top electrode TE. The magnetic tunnel junction pattern MTJ may include the same components as one of the magnetic tunnel junction patterns MTJ described with reference to FIGS. 2 to 5. In an implementation, as described with reference to FIG. 2, the magnetic tunnel junction pattern MTJ may include a first magnetic pattern MP1, a second magnetic pattern MP2, a tunnel barrier pattern TBR between the first magnetic pattern MP1 and the second magnetic pattern MP2, a seed pattern 140 between the bottom electrode BE and the first magnetic pattern MP1, a first diffusion barrier pattern 130A between the bottom electrode BE and the seed pattern 140, a blocking pattern 120 between the bottom electrode BE and the first diffusion barrier pattern 130A, a capping pattern 160 between the second magnetic pattern MP2 and the top electrode TE, and a non-magnetic pattern 150 between the second magnetic pattern MP2 and the capping pattern 160.

In an implementation, a top surface of the first interlayer insulating layer 110 may be recessed toward the substrate 100 between the plurality of data storage patterns DS. A protective insulating layer 170 may surround a sidewall of each of the plurality of data storage patterns DS. The protective insulating layer 170 may cover sidewalls of the bottom electrode BE, the magnetic tunnel junction pattern MTJ and the top electrode TE and may surround the sidewalls of the bottom electrode BE, the magnetic tunnel junction pattern MTJ and the top electrode TE when viewed in a plan view. The protective insulating layer 170 may extend from the sidewall of each of the plurality of data storage patterns DS onto the recessed top surface 110RU of the first interlayer insulating layer 110. The protective insulating layer 170 may conformally cover the recessed top surface 110RU of the first interlayer insulating layer 110. The protective insulating layer 170 may include a nitride (e.g., silicon nitride).

A second interlayer insulating layer 180 may be on the first interlayer insulating layer 110 and may cover the plurality of data storage patterns DS. The protective insulating layer 170 may be between the second interlayer insulating layer 180 and the sidewall of each of the plurality of data storage patterns DS and may extend between the second interlayer insulating layer 180 and the recessed top surface 110RU of the first interlayer insulating layer 110.

A plurality of upper interconnection lines 200 may be on the second interlayer insulating layer 180. The plurality of upper interconnection lines 200 may extend in the second direction D2 and may be spaced apart from each other in the third direction D3. Each of the plurality of upper interconnection lines 200 may be connected to the data storage patterns DS spaced apart from each other in the second direction D2.

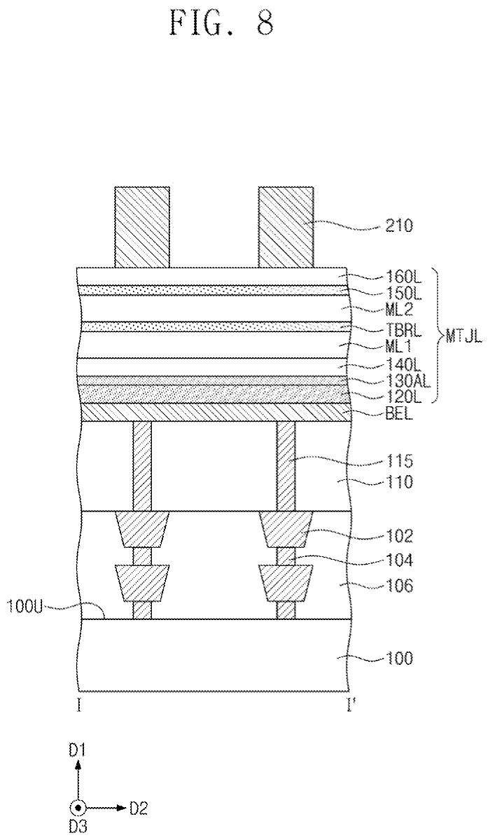

FIGS. 8 to 10 are cross-sectional views corresponding to the line I-I′ of FIG. 6 to illustrate stages in a method of manufacturing a magnetic memory device, according to some embodiments. Hereinafter, the descriptions to the same features as described with reference to FIGS. 2 to 7 may be omitted or mentioned briefly for the purpose of ease and convenience in explanation.

Referring to FIG. 8, selection elements (see SE of FIG. 1) may be formed in a substrate 100, and lower interconnection lines 102 and lower contacts 104 may be formed on the substrate 100. Each of the lower interconnection lines 102 may be electrically connected to one terminal of a corresponding one of the selection elements through a corresponding one of the lower contacts 104. A lower interlayer insulating layer 106 may be formed on the substrate 100 to cover the lower interconnection lines 102 and the lower contacts 104. Top surfaces of uppermost ones of the lower interconnection lines 102 may be substantially coplanar with a top surface of the lower interlayer insulating layer 106.

A first interlayer insulating layer 110 may be formed on the lower interlayer insulating layer 106, and a plurality of lower contact plugs 115 may be formed in the first interlayer insulating layer 110. Each of the plurality of lower contact plugs 115 may penetrate the first interlayer insulating layer 110 and may be connected to a corresponding one of the lower interconnection lines 102. In an implementation, the formation of the plurality of lower contact plugs 115 may include forming lower contact holes penetrating the first interlayer insulating layer 110, forming a lower contact layer filling the lower contact holes on the first interlayer insulating layer 110, and planarizing the lower contact layer until a top surface of the first interlayer insulating layer 110 is exposed.

A bottom electrode layer BEL and a magnetic tunnel junction layer MTJL may be sequentially formed on the first interlayer insulating layer 110. In an implementation, the magnetic tunnel junction layer MTJL may include a blocking layer 120L, a first diffusion barrier layer 130AL, a seed layer 140L, a first magnetic layer ML1, a tunnel barrier layer TBRL, a second magnetic layer ML2, a non-magnetic layer 150L and a capping layer 160L, which are sequentially stacked on the bottom electrode layer BEL. The bottom electrode layer BEL and the magnetic tunnel junction layer MTJL may be formed by, e.g., a sputtering process, a chemical vapor deposition (CVD) process, or an atomic layer deposition (ALD) process.

Conductive mask patterns 210 may be formed on the magnetic tunnel junction layer MTJL. The conductive mask patterns 210 may define regions in which magnetic tunnel junction patterns will be formed. In an implementation, the conductive mask patterns 210 may include, e.g., a metal (e.g., Ta, W, Ru, or Ir) or a conductive metal nitride (e.g., TiN).

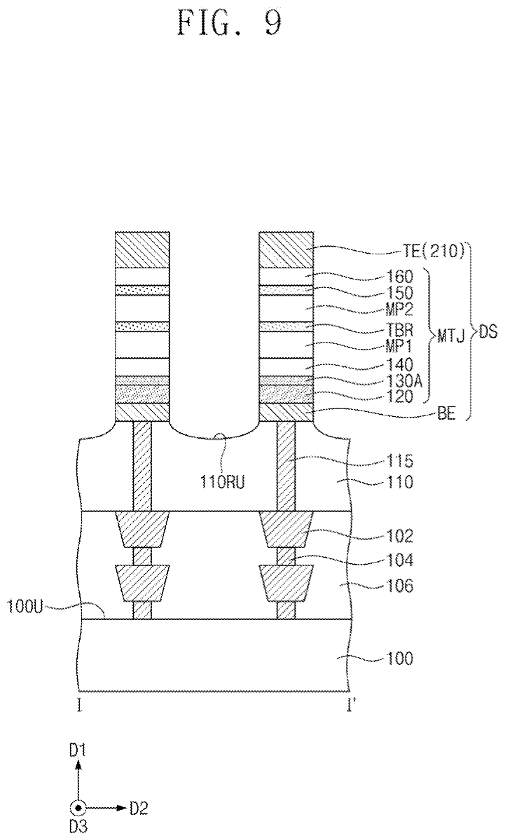

Referring to FIG. 9, the magnetic tunnel junction layer MTJL and the bottom electrode layer BEL may be sequentially etched using the conductive mask patterns 210 as etch masks. Thus, magnetic tunnel junction patterns MTJ and bottom electrodes BE may be formed on the first interlayer insulating layer 110. The bottom electrodes BE may be connected to the lower contact plugs 115, respectively, and the magnetic tunnel junction patterns MTJ may be formed on the bottom electrodes BE, respectively.

The etching of the magnetic tunnel junction layer MTJL may include sequentially etching the capping layer 160L, the non-magnetic layer 150L, the second magnetic layer ML2, the tunnel barrier layer TBRL, the first magnetic layer ML1, the seed layer 140L, the first diffusion barrier layer 130AL, and the blocking layer 120L by using the conductive mask patterns 210 as etch masks. Thus, each of the magnetic tunnel junction patterns MTJ may include a blocking pattern 120, a first diffusion barrier pattern 130A, a seed pattern 140, a first magnetic pattern MP1, a tunnel barrier pattern TBR, a second magnetic pattern MP2, a non-magnetic pattern 150 and a capping pattern 160, which are sequentially stacked on each of the bottom electrodes BE.

An etching process of etching the magnetic tunnel junction layer MTJL and the bottom electrode layer BEL may include, e.g., an ion beam etching process using an ion beam. The ion beam may include ions of an inert gas. A top surface of the first interlayer insulating layer 110 may be recessed between the magnetic tunnel junction patterns MTJ by the etching process. Thus, the first interlayer insulating layer 110 may have the recessed top surface 110RU between the magnetic tunnel junction patterns MTJ.

After the etching process, remaining portions of the conductive mask patterns 210 may remain on the magnetic tunnel junction patterns MTJ, respectively. The remaining portions of the conductive mask patterns 210 may function as top electrodes TE. Hereinafter, the remaining portions of the conductive mask patterns 210 may be referred to as top electrodes TE. The top electrodes TE, the magnetic tunnel junction patterns MTJ, and the bottom electrodes BE may constitute data storage patterns DS, and each of the data storage patterns DS may include the bottom electrode BE, the magnetic tunnel junction pattern MTJ and the top electrode TE which are sequentially stacked on a corresponding lower contact plug 115.

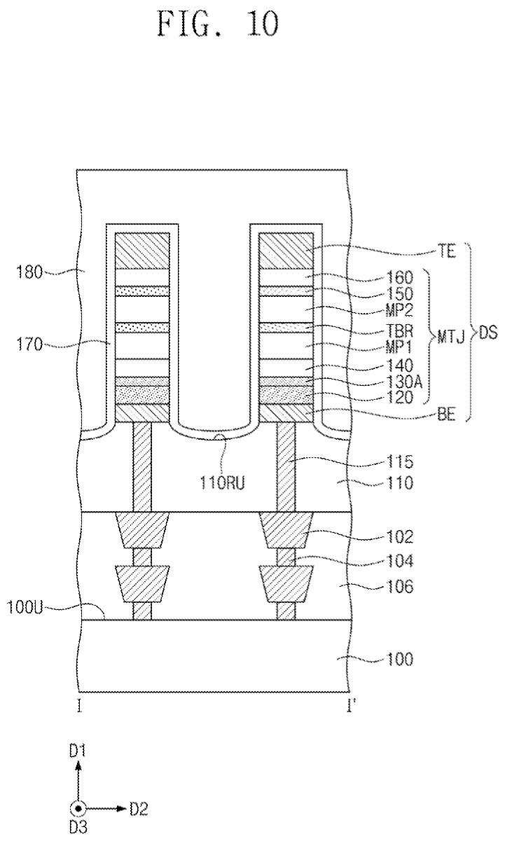

Referring to FIG. 10, a protective insulating layer 170 may be formed on the first interlayer insulating layer 110 to cover the data storage patterns DS. The protective insulating layer 170 may be formed to conformally cover a top surface and a sidewall of each of the data storage patterns DS and may extend along the recessed top surface 110RU of the first interlayer insulating layer 110. A second interlayer insulating layer 180 may be formed on the protective insulating layer 170 to cover the data storage patterns DS.

Referring again to FIG. 7, portions of the second interlayer insulating layer 180 and the protective insulating layer 170 may be removed to expose a top surface of the top electrode TE of each of the data storage patterns DS. An upper interconnection line 200 may be formed on the second interlayer insulating layer 180 and may cover the exposed top surface of the top electrode TE. The upper interconnection line 200 may be electrically connected to the top electrode TE.

According to the embodiments, at least one diffusion barrier pattern 130A may be under the seed pattern 140, and thus it is possible to help prevent metal atoms in lower patterns (e.g., the bottom electrode BE) under the diffusion barrier pattern 130A from being diffused into the seed pattern 140 and upper patterns (e.g., the first magnetic pattern MP1) on the seed pattern 140. As a result, deterioration of crystallinity of the seed pattern 140 and the first magnetic pattern MP1 may be prevented to improve a tunnel magnetoresistance (TMR) characteristic of the magnetic tunnel junction pattern MTJ and high-temperature reliability of the magnetic tunnel junction pattern MTJ.

By way of summation and review, highly integrated and/or low-power magnetic memory devices have been increasingly demanded with the development of an electronic industry. Thus, satisfying these concerns has been considered.

Accordingly, the magnetic memory device with the improved high-temperature reliability and TMR characteristic may be provided or realized.

At least one diffusion barrier pattern may be under the seed pattern, and thus it is possible to prevent metal atoms in lower patterns (e.g., the bottom electrode) under the diffusion barrier pattern from being diffused into the seed pattern and upper patterns (e.g., the first magnetic pattern) on the seed pattern. Thus, deterioration of crystallinity of the seed pattern and the first magnetic pattern may be prevented. As a result, the tunnel magnetoresistance (TMR) characteristic of the magnetic tunnel junction pattern may be improved, and the high-temperature reliability of the magnetic tunnel junction pattern may be improved. Accordingly, the magnetic memory device with the improved high-temperature reliability and TMR characteristic may be provided or realized.

One or more embodiments may provide a magnetic memory device capable of improving high-temperature reliability.

One or more embodiments may provide a magnetic memory device capable of improving a tunnel magnetoresistance (TMR) characteristic.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A magnetic memory device, comprising:
a substrate;
a first magnetic pattern and a second magnetic pattern sequentially stacked on the substrate;
a tunnel barrier pattern between the first magnetic pattern and the second magnetic pattern;
a bottom electrode between the substrate and the first magnetic pattern;
a seed pattern between the bottom electrode and the first magnetic pattern; and
at least one diffusion barrier pattern between the bottom electrode and the seed pattern,
wherein:
a bottom surface of the at least one diffusion barrier pattern is in contact with a top surface of the bottom electrode, and a top surface of the at least one diffusion barrier pattern is in contact with a bottom surface of the seed pattern,
the at least one diffusion barrier pattern includes:
a non-magnetic metal, or
an alloy of the non-magnetic metal and a non-metal element, and
the non-magnetic metal includes Ta, W, Nb, Ti, Cr, Zr, Hf, Mo, Al, Mg, or V.

2. The magnetic memory device as claimed in claim 1, wherein the non-metal element includes Si, N, or B.

3. The magnetic memory device as claimed in claim 1, wherein the at least one diffusion barrier pattern is a crystalline layer of the non-magnetic metal.

4. The magnetic memory device as claimed in claim 3, wherein:
each of the seed pattern and the at least one diffusion barrier pattern has a thickness in a first direction perpendicular to a top surface of the substrate, and
the thickness of the at least one diffusion barrier pattern is less than the thickness of the seed pattern.

5. The magnetic memory device as claimed in claim 4, wherein:
the bottom electrode has a thickness in the first direction, and
the thickness of the at least one diffusion barrier pattern is less than the thickness of the bottom electrode.

6. The magnetic memory device as claimed in claim 5, wherein the thickness of the at least one diffusion barrier pattern ranges from 5 Å to 15 Å.

7. The magnetic memory device as claimed in claim 1, wherein:
the at least one diffusion barrier pattern includes:
a first diffusion barrier pattern adjacent to the seed pattern; and
a second diffusion barrier pattern adjacent to the bottom electrode,
the first diffusion barrier pattern includes a first non-magnetic metal or an alloy of the first non-magnetic metal and a first non-metal element,
the second diffusion barrier pattern includes a second non-magnetic metal or an alloy of the second non-magnetic metal and a second non-metal element, and
each of the first non-magnetic metal and the second non-magnetic metal independently includes Ta, W, Nb, Ti, Cr, Zr, Hf, Mo, Al, Mg, or V.

8. The magnetic memory device as claimed in claim 7, wherein each of the first non-metal element and the second non-metal element includes Si, N, or B.

9. The magnetic memory device as claimed in claim 7, wherein the second diffusion barrier pattern includes a different material from that of the first diffusion barrier pattern.

10. A magnetic memory device, comprising:
a substrate;
a first magnetic pattern and a second magnetic pattern sequentially stacked on the substrate;
a tunnel barrier pattern between the first magnetic pattern and the second magnetic pattern;
a bottom electrode between the substrate and the first magnetic pattern;
a seed pattern between the bottom electrode and the first magnetic pattern; and
a first diffusion barrier pattern between the bottom electrode and the seed pattern,
wherein:
the first diffusion barrier pattern includes:
a first non-magnetic metal, or
an alloy of the first non-magnetic metal and a first non-metal element, and
the first non-magnetic metal includes W, Nb, Ti, Cr, Zr, Hf, Mo, Al, Mg, or V.

11. The magnetic memory device as claimed in claim 10, wherein the first non-metal element includes Si, N, or B.

12. The magnetic memory device as claimed in claim 10, further comprising a blocking pattern between the bottom electrode and the first diffusion barrier pattern,
wherein the blocking pattern includes an amorphous metal layer.

13. The magnetic memory device as claimed in claim 12, wherein the first diffusion barrier pattern is a crystalline layer of the first non-magnetic metal.

14. The magnetic memory device as claimed in claim 13, wherein:
each of the blocking pattern and the first diffusion barrier pattern has a thickness in a first direction perpendicular to a top surface of the substrate, and
the thickness of the first diffusion barrier pattern is less than the thickness of the blocking pattern.

15. The magnetic memory device as claimed in claim 14, wherein:
the seed pattern has a thickness in the first direction, and
the thickness of the first diffusion barrier pattern is less than the thickness of the seed pattern.

16. The magnetic memory device as claimed in claim 10, wherein each of the first and second magnetic patterns has a magnetization direction substantially perpendicular to an interface of the first magnetic pattern and the tunnel barrier pattern.

17. A magnetic memory device, comprising:
a substrate;
a first magnetic pattern and a second magnetic pattern sequentially stacked on the substrate;
a tunnel barrier pattern between the first magnetic pattern and the second magnetic pattern;
a bottom electrode between the substrate and the first magnetic pattern;
a seed pattern between the bottom electrode and the first magnetic pattern; and
a first diffusion barrier pattern between the bottom electrode and the seed pattern,
wherein:
the first diffusion barrier pattern is a crystalline layer of a first non-magnetic metal, and
the first non-magnetic metal includes W, Nb, Ti, Cr, Zr, Hf, Mo, Al, Mg, or V.

18. The magnetic memory device as claimed in claim 17, wherein:
each of the seed pattern and the first diffusion barrier pattern has a thickness in a first direction perpendicular to a top surface of the substrate, and
the thickness of the first diffusion barrier pattern is less than the thickness of the seed pattern.

19. The magnetic memory device as claimed in claim 17, further comprising a blocking pattern between the bottom electrode and the first diffusion barrier pattern,
wherein the blocking pattern includes an amorphous metal layer.

20. The magnetic memory device as claimed in claim 19, wherein:
each of the seed pattern, the first diffusion barrier pattern, and the blocking pattern has a thickness in a first direction perpendicular to a top surface of the substrate, and
the thickness of the first diffusion barrier pattern is less than the thickness of the seed pattern and is less than the thickness of the blocking pattern.
